(19) United States
(12) Patent Application Publication
(10) Pub. No.: US 2002/0121915 A1
(43) Pub. Date: Sep. 5, 2002

(54) Automated pattern clustering detection for wafer probe maps

(75) Inventors: Juan Ignacio Alonso Montull, Madrid (ES); Carlos Ortega, Madrid (ES); Eliseo Ventura Sobrino Patino, Bethlehem, PA (US); Julia Maria Villen Pizarro, Madrid (ES)

Correspondence Address: CHRISTOPHER F. REGAN, Allen, Dyer, Doppelt, Milbrath & Gilchrist, P.A., P.O. Box 3791, Orlando, FL, 32802-3791, US

(73) Assignee: Agere Systems Guardian Corp., Miami Lakes, FL (US)

(21) Appl. No.: 09/799,337

(22) Filed: Mar. 5, 2001

(51) Int. Cl. G01R 31/26

(52) U.S. Cl. 324/765

(57) ABSTRACT

A method for characterizing defects of integrated circuits on a semiconductor wafer includes storing at least one reference wafer map in a memory corresponding to a known defect pattern of the integrated circuits caused during a manufacturing step thereof, testing the integrated circuits for defects, generating a test wafer map for the semiconductor wafer comprising a pattern of each defective integrated circuit thereon, comparing the test wafer map to the at least one reference wafer map to determine if the known defect pattern is present in the test wafer map, and generating a new reference wafer map corresponding to the test wafer map if the test wafer map has an unknown defect pattern. An apparatus for characterizing defects of integrated circuit die on a semiconductor wafer is also provided.

### FIELD OF THE INVENTION

The present invention relates generally to the field of semiconductor devices, and, more particularly, to a method for processing analytical results from test probes of wafers to determine causes of defective die.

### BACKGROUND OF THE INVENTION

The manufacture of integrated circuit (IC) devices requires many complex operating steps to transform a semiconductive wafer into a large number of packaged IC devices. Typical processing steps include planarization, layering, patterning, doping, heat treatment, etching, metallization, singulation, packaging and testing. Each step in the process provides opportunities for introduction of defects of various types into the IC devices. Defects fatal to the operability of a circuit or die may be caused, for example, by variations in the original semiconductor material, introduction of contaminants (dust, chemicals, gases, etc.), non-uniform layering and/or etching, and variations in doping materials, heat exposure, and other processing conditions.

Because of the large number of manufacturing steps, tests are typically conducted at various stages to identify defective wafers or wafer portions. The spatial characterization of defects is generally defined in terms of the particular die which are affected. Usually, the term “defect” refers to a “fatal” defect, i.e., a defect which will cause rejection of a die. From these tests, the step yields and overall die yield may be determined. The overall die yield is the percentage of possible die sites of a starting wafer which are successfully fabricated, packaged and tested for the intended use.

The so-called die yield is normally considered to be a product of several step yields, including (1) wafer yield, or the fraction of cut wafers that complete processing, (2) process yield, or the fraction of die on the wafers that complete processing, (3) assembly yield, or the fraction of good die which are successfully packaged, and (4) burn-in yield, or the fraction of good packaged devices which are successfully functional after a stress test. A die is generally determined by the tests to be either acceptable or unacceptable. The criterion for accept/non-accept is based on the requirements of the intended application, although a fatal defect relative to an intended application may be benign in some other application. It is, of course, not economic to continue the manufacturing process on die which have fatal defects.

Because of the wide variety of detectable defect types and the large number of possible underlying causes, analysis of defects has presented several challenging problems, including the design of instruments for rapid, non-destructive detection and definition of the various types of defects, assigning a particular cause to each detected defect, and determining what actions are required to avoid the defect in the future. As improvements in the various IC manufacturing steps have enabled more rapid and nearly continuous fabrication, a major challenge has been the ability to test wafers for defects and quickly determine the causes of the defects which are found to correct the process before further wafers are processed. To provide an effective on-line feedback system to maximize yield, the time required for wafer testing and test data analysis is desirably minimized.

New processing methods and test methods are continually being developed to handle wafer designs which are increasing in density. Thus, it is desirable to fully characterize current and future manufacturing methods by the resulting characteristics of the produced wafers and die to improve functionality and increase yield.

A current method of relating defects to particular process faults is described in U.S. Pat. No. 5,240,866 of Friedman et al. In this method, the defective circuits (i.e., die) of a lot of tested wafers are first mapped for each wafer. Possible spatial clustering of failed circuits is determined through the use of a neural network or other computational method. In this method, a weighted average of the number of defective die contiguous to each defective die of the wafer is calculated and transformed by an arc-sine square-root transformation. Die having a transformed value greater than an assigned value are considered to be part of a spatial cluster of defects.

The transformed values are then standardized and mapped using a normal probability integral transformation. The mapped values are compared to a prescribed threshold value to classify each value as binary 1 or 0. It is assumed that non-clustered defects are random noise and are therefore removed from consideration in the algorithm. A map is formed for each wafer of the lot, indicating the cluster pattern(s) so formed.

In a next step, all of the tested wafers are then combined as a single analysis lot. All wafers of the analysis lot are compared with each other and grouped on the basis of similar defect cluster patterns. Any particular cluster pattern which occurs on more than one wafer in the wafer lot is further analyzed to determine its probable cause. A defect cluster which appears on only one wafer is treated as being not statistically significant. Significant cluster patterns are then analyzed in accordance with the order of step processing, the particular processing machine or line, and other process variables to identify the probable causes of the defect clusters. Recurrent cluster patterns may also be compared to cluster patterns known to be associated with particular process faults.

The complete analysis including the statistical calculations may be conducted manually. However, this would require an undue amount of labor, and would take considerable time to complete. In order to complete the analysis in a shorter time, the various steps in data analysis are conducted by computer with commercially available clustering and statistics software.

In practice, the above method has significant shortcomings. First, the cluster patterns defined for analysis do not include patterns which appear on only one wafer of the lot. Thus, cluster patterns of defects which may be of importance in the manufacturing process are simply ignored. There may be, for example, a considerable number of controllable defect pattern types which appear on only one wafer of a wafer lot. An occurrence of a pattern type on only one wafer may be considered statistically insignificant. Nevertheless, process changes to avoid these defects may significantly enhance the overall yield.

Secondly, the above prior art method requires a minimum of two wafers to achieve its goal, i.e., finding multiple wafers with the same defect pattern. It would be desirable to be able to probe and process the first wafer of a wafer lot to find and characterize any defect pattern clusters which may exist to make improvements in the manufacture of subsequent wafers.

U.S. Pat. No. 5,787,190 to Peng et al. describes a similar method for finding statistically significant fault patterns in a wafer lot. In this method, however, test bin data from at least one wafer lot are processed by a neural network (NN) to generate a representative neural network wafer map. Individual semiconductor wafers are then analyzed by (a) an in-line defect tester, (b) a wafer electrical tester, (c) a wafer level reliability tester, and (d) external analysis. Each test contributes to the production of a wafer fault map for all wafers of the lot relative to one of the four test procedures (a), (b), (c), or (d), above. Each wafer fault map is compared to the NN wafer map to determine overlap.

Numerous problems exist in the use of neural networks as pattern detection tools, making the method laborious, time-consuming, and prone to errors. A high number of “training examples” are required to obtain a reasonable minimum error. Also, it is difficult to fully comprehend what the net is doing in the analysis. Constant fine tuning of the net is also required. Thus, the analysis requires a great deal of a statistician's personal attention, and the method is time-consuming. Consequently, the method is not generally useful as an in-line tool for quick analysis and process correction.

### SUMMARY OF THE INVENTION

In view of the foregoing background, it is therefore an object of the present invention is to provide a test analysis method which is straightforward, and may be readily performed on a single wafer with minimum personal attention, rapid completion, and high accuracy.

The present invention relates to a pattern detection tool and a method for finding pre-defined patterns of interest on a semiconductor wafer based on the results of tests conducted on each die of the wafer. A probed wafer may be monitored for the presence of a pre-defined cluster pattern(s) of defects or other measurable factors. The test results may be in the form of a detectable characterization and are not limited to fatal defects.

A method aspect of the invention is for characterizing defects of integrated circuits on a semiconductor wafer. The method includes storing at least one reference wafer map in a memory corresponding to a known defect pattern of the integrated circuits caused during a manufacturing step thereof, testing the integrated circuits for defects, and generating a test wafer map for the semiconductor wafer including a pattern of each defective integrated circuit thereon. The test wafer map may be compared to the at least one reference wafer map to determine if the known defect pattern is present in the test wafer map. Further, a new reference wafer map may be generated corresponding to the test wafer map if the test wafer map has an unknown defect pattern.

An apparatus for characterizing defects of integrated circuits on a semiconductor wafer according to the invention includes a test probe for testing the integrated circuit for defects, a memory for storing at least one reference wafer map corresponding to a known defect pattern of the integrated circuits caused during a manufacturing step thereof, and a processor connected to the test probe and the memory. The processor may generate a test wafer map for the semiconductor wafer including a pattern of each defective integrated circuit thereon. The processor may also compare the test wafer map to the at least one reference wafer map to determine if the known defect pattern is present in the test wafer map. Furthermore, the processor may generate a new reference wafer map corresponding to the test wafer map if the test wafer map has an unknown defect pattern.

### BRIEF DESCRIPTION OF THE DRAWINGS

FIG. 1 is a perspective view of a semiconductor wafer having a plurality of die thereon and a testing probe used to conduct tests which are analyzed in accordance with a method of the present invention.

FIG. 2 is a top view of a semiconductor wafer map of a wafer having an exemplary cluster pattern of defective die thereon for processing in accordance with a method of the invention.

FIG. 3 is a top view of a semiconductor wafer map of another wafer having another exemplary cluster pattern of defective die thereon for processing in accordance with a method of the invention.

FIG. 4 is a flowchart showing steps in analyzing wafers for cluster patterns in accordance with a method of the invention.

FIG. 5 is a top view of a pre-defined pseudo-wafer map useful for cluster pattern analysis in accordance with a method of the invention.

FIG. 6 is a top view of another pre-defined pseudo-wafer map useful for cluster pattern analysis in accordance with a method of the invention.

### DETAILED DESCRIPTION OF THE PREFERRED EMBODIMENTS

The present invention will now be described more fully hereinafter with reference to the accompanying drawings, in which preferred embodiments of the invention are shown. However, this invention may be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

The method of the invention includes steps for performing an analysis of defect patterns in semiconductor wafers, and may be used at various stages of manufacture where tests are conducted. It is particularly useful the correlating the results of tests conducted at “wafer sort”, i.e., prior to die singulation and packaging, inasmuch as these tests are critical. At this stage, defects found by various test procedures may be related to particular faults in the manufacturing process.

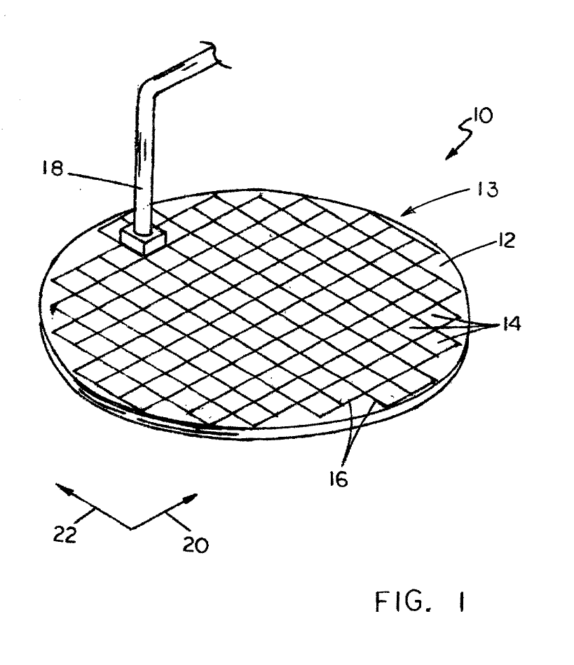

As illustrated in FIG. 1, a semiconductor wafer 10 typically has an active surface 12 on which a matrix 13 of integrated circuits or die 14 are formed. The integrated circuits 14 may include elements such as transistors, resistors, capacitors, conductors, etc. Individual circuits 14 are shown as die bounded by scribe lines 16 which run parallel to x-axis 20 and the perpendicular y-axis 22.

Ordinarily, before a wafer 10 is singulated into separate die 14, various tests are conducted, including probe tests by a probe instrument 18. These tests (including so-called “parametric” circuit tests) result in a characterization of each die 14 of the wafer 10, and thus a characterization of the entire wafer. Each die 14 of a wafer will be associated with a wafer test bin including data identified by an alphanumeric code which represents the characteristics of functional and non-functional die. The wafer test bins are grouped to generate a bin summary or wafer map indicating the locations of die 14 which fail the test. In addition to identifying usable die 14, the tests are conducted to pinpoint the causes of particular problems, the goal being correction of the manufacturing process to eliminate the defect and improve the yield in other wafers 10 of the lot. There are typically about 25-50 wafers per lot.

In addition to certain defects whose cause may be known, other defects (certain circuit defects) may be considered to be random in nature, even though a cause does of course exist, and there may be discernable. An example of a random defect may be one caused by an air-borne contaminant particle. Even with a random defect, it may be possible to determine the particular step in which the contaminant was introduced, so that improvements may be initiated to reduce contamination in that step, for example.

A primary test procedure includes parametric electrical circuit tests to determine functionality of each die 14. The electrical probe instrument 18 positions needle-like probes on the surface 12 of a die 14 and applies varied voltage, current and polarity to the die. Furthermore, a multiprobe card may simultaneously test a plurality of die 14 on a wafer 10. Non-contact methods are also available for performing circuit tests and other tests. Measured circuit variables may be used to determine current/voltage relationships, resistance, resistivity, diode forward voltage, leakage current, breakdown voltage, beta value, capacitance, and the like.

Defects may be classified as being large area defects or point defects. Examples of large area defects include surface scratches, incomplete etches, areas of non-uniform deposition thickness, and wafer non-planarity. Point defects are generally defined as those which appear to be much smaller in area. Examples include voids (pinholes) in layers, protrusions (bridges), and random spot defects. Point defects may, however, result from processing steps affecting large areas. They may include, for example, stacking faults, slip, and dislocations which result from poorly designed thermal processes, incomplete annealing, and/or unsatisfactory epitaxial growth steps.

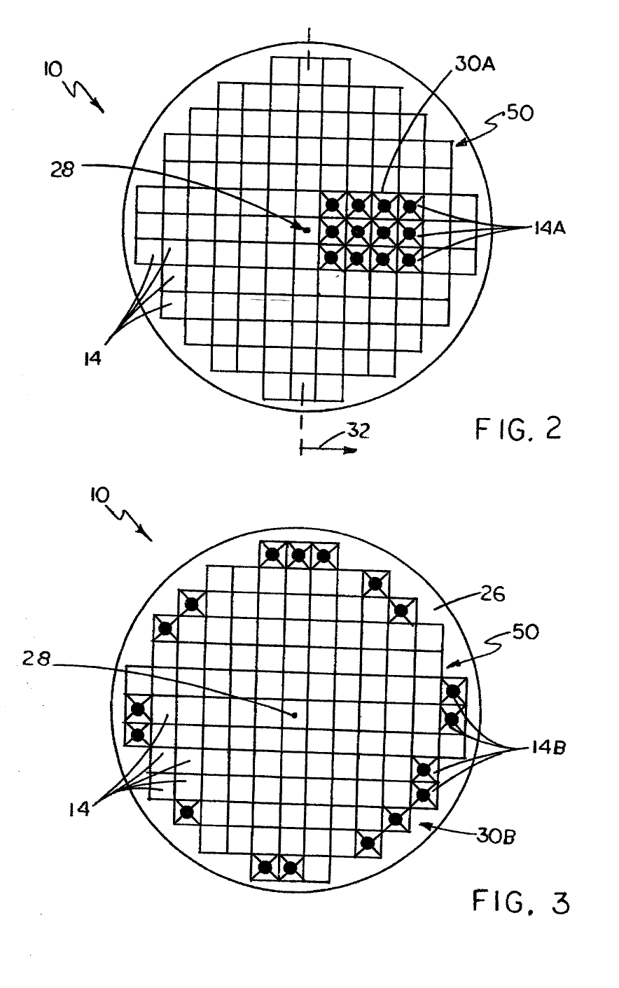

The die 14 which fail a particular test may be clustered in a specific spatial location or locations on a wafer surface 12. For example, as shown in the wafer map of FIG. 2, a particular manufacturing error may result in a group of defective die 14A which are in a right side 32, near the center 28 of an exemplary wafer 10A. These twelve defective die 14A together form a cluster pattern 30A. Likewise, another wafer 10B is illustrated in FIG. 3 on which a group of defective die 14B form a ring or round cluster pattern 30B near the periphery 26. The cluster pattern 30B is shown as circumferential about wafer center 28.

In a typical analysis method of the prior art, a cluster pattern 30 is considered to be a pattern of spatially adjacent die 14 having the same type of defect, where the cluster pattern is recurrent in other wafers 10 in the wafer lot. Since the method matches probed wafer maps with other probed wafer maps, at least two probed wafer maps are required. A defect cluster pattern 30 found on one wafer 10 is thus considered significant when at least one other wafer of the wafer lot has the same pattern.

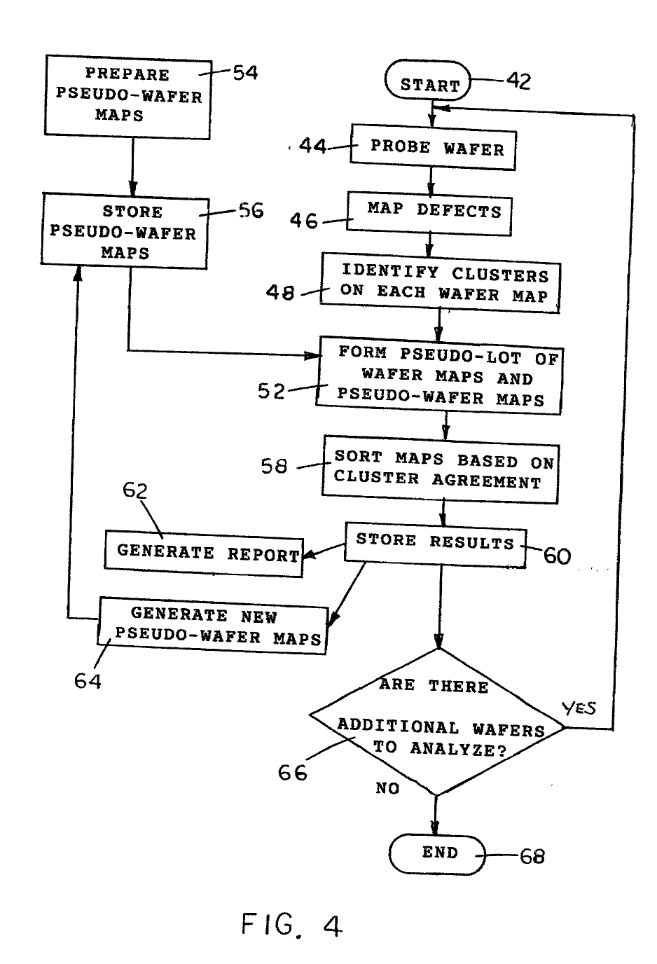

Turning now to FIG. 4, an example of the method of the invention is now described. When a wafer 10 reaches a stage in manufacture that it is ready to be tested, the method of the invention is started, as shown in Block 42. Each die 14 on a wafer 10 is probed for disabling defects (Block 44). Each defective die is associated with a particular spatial location, for example, defined by x and y coordinates 20 and 22, respectively, on the wafer 10. As depicted in Block 46, the defective die 14A may be notated on a wafer map 50. A computer (not shown) processes the data in digital form.

As indicated in Block 48, some or all of the defective die 14A in a wafer 10 may be in spatial clusters having a similar defect type.

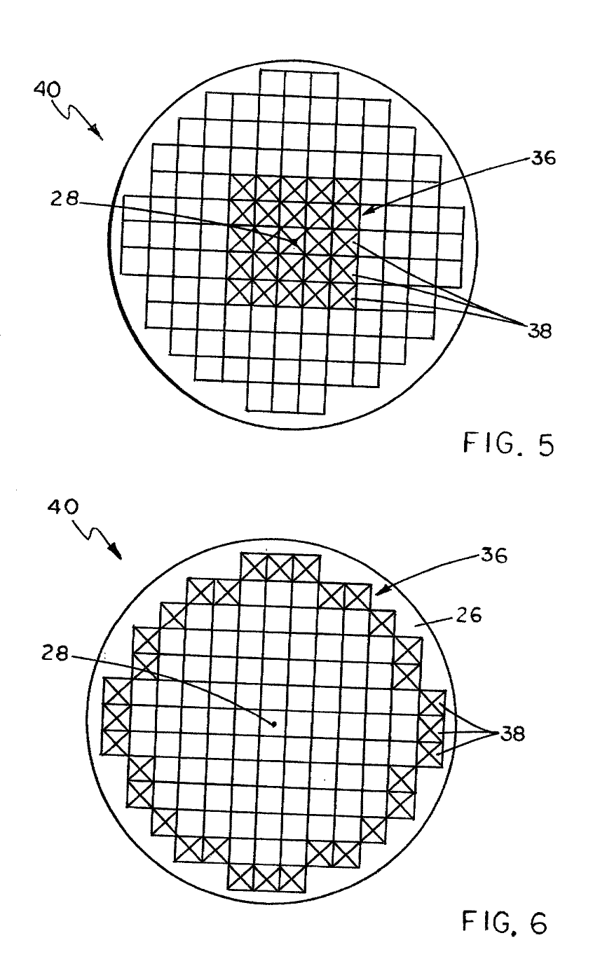

One or more reference or pseudo-wafer maps 40 are prepared (Block 54) as models to which wafer maps 50 will be compared. Each has a pre-determined defect cluster pattern 36 (see FIGS. 5 and 6) which is of interest, e.g., which is known to result from a specific process fault. Exemplary pseudo-wafer maps 40 with defined cluster patterns 36 of pseudo-die 38 are shown in FIGS. 5 and 6.

FIG. 5 illustrates a cluster pattern 36 including a central portion about wafer center 28 of pseudo-map 40. All defective die 14 in a wafer test which substantially correspond to this area will be considered as this type of defect. FIG. 6 illustrates a cluster pattern 36 including an outer round or ring pattern in the outermost pseudo-die 38, near the periphery 26 of the pseudo-wafer map 40. Such cluster patterns 36 are commonly associated with specific process operations in IC manufacture. The particular mathematical representation of this type of cluster pattern 36 may also include rings (not shown) of a smaller diameter (i.e., not in the outermost die 38).

Pseudo-wafer maps 40 are stored (Block 56) in a library for use as wafer characterization tools in the present invention. As seen in Block 52 of FIG. 4, selected pseudo-wafer maps 40 are combined with the wafer map or maps 50, as a reference or pseudo-lot. The pseudo-lot of maps 40 and 50 is then subjected in Block 58 to a comparison step whereby the pattern(s) 30 on wafer map(s) 50 and the pattern(s) 36 on the pseudo-wafer map(s) 50 are cross-compared and sorted according to corresponding or similar cluster patterns which characterize the sorted group. In this sorting step 58, groups of wafers 10 having corresponding or similar cluster patterns will include single wafers having the sole occurrence of a particular defect.

The characterization data for each wafer 10 and die 14 on the wafer is stored (e.g., in computer memory) as shown in Block 60. A wafer report may be generated (Block 62). Such a report is useful for specifying alterations in the manufacturing process.

In addition, if a particular defect cluster 30 appears which has a different shape, etc. the method includes generation of a new pseudo-wafer map 40 in Block 64, for use with future wafer testing. This map 40 may be stored in a pseudo-wafer map library together with other maps 40 in Block 56.

It is noted that the steps of FIG. 4 are conducted using software routines, wherein the method is conducted automatically to provide wafer characterization information very quickly. There are various commercial software programs which have comparison-sorting routines which may be used in this invention. For example, certain routines of a mathematical/statistical software program known as S-Plus, available from MathSoft Inc., may be combined with S-Wafers, a graphical user interface (GUI) developed by Bell Laboratories.

A series of pseudo-wafer maps 40 may be used which will encompass substantially all defect patterns 30 detected by probing a wafer 10. For example, such a series may include the following defect patterns:

(1) A rounded failure shape affecting a central portion of the wafer;

(2) A rounded failure shape affecting the whole periphery of the wafer;

(3) Failure at the center and edge of the wafer;

(4) Failures affecting the upper left corner of the wafer;

(5) Failures affecting the upper right corner of the wafer;

(6) Failures affecting the lower left corner of the wafer;

(7) Failures affecting the lower right corner of the wafer;

(8) One vertical failure shape from the upper part of the wafer to the wafer center;

(9) One vertical failure shape from the lower part of the wafer to the wafer center;

(10) Failures in alternate vertical lines;

(11) Failures in alternate horizontal lines;

(12) Failures in both vertical and horizontal lines (trellis shape);

(13) General failure in the left side portion of the wafer;

(14) General failure in the right side portion of the wafer;

(15) General failure in the upper portion of the wafer;

(16) General failure in the lower portion of the wafer;

(17) Random failure in the whole wafer;

(18) Round shape failure in the lower portion of the wafer;

(19) Round shape failure in the upper portion of the wafer;

(20) Round shape failure in the left side portion of the wafer;

(21) Round shape failure in the right side portion of the wafer; and

(22) Ad hoc shape to cover a particular failure such as a scratch.

Each of the above pattern definitions is known to be related to specific types of processing faults.

In general, the preferred pattern definition in each pseudo-wafer map 40 is two-fold. That is, it indicates a general shape or type of defect pattern 30 as well as the wafer location in which the pattern appears.

### EXAMPLE

A simple example will illustrate the effectiveness of the present invention as compared to prior art methods.

Assume that a wafer lot includes 25 individual wafers. Parametric tests indicate defects which are classified by location (center, top, bottom, left, or right, for example):

(a) 10 wafers have a clear pattern of failing devices in the upper portion of the wafer;

(b) 5 wafers have defects in the central portion;

(c) 9 wafers do not show any pattern of defects; and

(d) 1 wafer has a defect in its left side.

In the method of the present invention, test data including wafer maps from the 25 wafers are grouped with one or more pseudo-maps defining types of defect locations, whether a single die or clustered die. This grouping, i.e. pseudo-lot is processed by software to provide a correlation of all defects of each wafer with at least one pseudo-map.

According to a prior art method of analysis, a statistical algorithm is used to detect defect clusters, i.e. defective die which abut each other. The tested wafers are grouped together as a lot and evaluated to find common patterns. Where a defective die pattern appears in at least two wafers, the pattern is treated and smoothed to eliminate defects not abutting the other pattern defects. Thus, in this example, the patterns (or lack of patterns) will be detected, i.e. in the wafers of (a), (b) and (c), above. The single wafer of (d) which has a pattern of defects in its left side will not be detected by the algorithm because the pattern occurs only once (i.e. in only one wafer). Thus, this defect will be deleted from the clustering calculations by a smoothing step.

In the present invention, the single wafer having a pattern of left-side defects will be detected by a pseudo-wafer map. As seen in this simple example, the present invention detects and accounts for all defects, both clustered and separate, even if they occur only once in the wafer lot.

Many modifications and other embodiments of the invention will come to the mind of one skilled in the art having the benefit of the teachings presented in the foregoing descriptions and the associated drawings. Therefore, it is to be understood that the invention is not to be limited to the specific embodiments disclosed, and that the modifications and embodiments are intended to be included within the scope of the dependent claims.

That which is claimed is:

1. A method for characterizing defects of integrated circuit die on a semiconductor wafer comprising:
storing at least one reference wafer map in a memory corresponding to a known defect pattern of the integrated circuits caused during a manufacturing step thereof;
testing the integrated circuit die on the semiwafer for defective integrated circuit die;
generating a test wafer map for the semiconductor wafer comprising a pattern of each defective integrated circuit die thereon;
comparing the test wafer map to the at least one reference wafer map to determine if the known defect pattern is present in the test wafer map; and
generating a new reference wafer map corresponding to the test wafer map if the test wafer map has an unknown defect pattern.

2. The method of claim 1 wherein the semiconductor wafer comprises a plurality of semiconductor wafers; and further comprising grouping test wafer maps having at least one common defect pattern.

3. The method of claim 2 further comprising generating a report indicating a frequency of test wafer maps having the at least one common defect pattern.

4. The method of claim 1 further comprising subjecting the test wafer pattern to a statistical smoothing operation to delete random defects.

5. The method of claim 1 wherein the at least one reference wafer map comprises a plurality of reference wafer maps and the semiconductor wafer comprises a plurality of semiconductor wafers; and further comprising grouping the plurality of reference wafer maps and the plurality of test wafer maps to provide a reference wafer lot.

6. The method of claim 1 further comprising storing the new reference wafer map in the memory.

7. A method for characterizing defects of integrated circuit die on a plurality of semiconductor wafers comprising:
storing a plurality of reference wafer maps in a memory each corresponding to a known defect pattern of the integrated circuits caused during a manufacturing step thereof;
testing the integrated circuit die on each semiconductor wafer for defective integrated circuit die;
generating a test wafer map for each semiconductor wafer comprising a pattern of each defective integrated circuit thereon;
comparing each of the test wafer maps to the plurality of reference wafer maps to determine if at least one known defect pattern is present in the test wafer map;
generating a new reference wafer map corresponding to each generated test wafer map having an unknown defect pattern; and
storing the new reference wafer map in the memory.

8. The method of claim 7 further comprising grouping test wafer maps having the at least one common defect pattern.

9. The method of claim 8 further comprising generating a report indicating a frequency of test wafer maps having the at least one common defect pattern.

10. The method of claim 7 further comprising subjecting each test wafer pattern to a statistical smoothing operation to delete random defects.

11. The method of claim 7 further comprising grouping the plurality of reference wafer maps and the plurality of test wafer maps to provide a reference wafer lot.

12. An apparatus for characterizing defects of integrated circuit die on a semiconductor wafer comprising:
a test probe for testing the integrated circuit die for defects;
a memory for storing at least one reference wafer map corresponding to a known defect pattern of the integrated circuit die caused during a manufacturing step thereof; and
a processor connected to said test probe and said memory, said processor
generating a test wafer map for the semiconductor wafer comprising a pattern of each defective integrated circuit die thereon,
comparing the test wafer map to the at least one reference wafer map to determine if the known defect pattern is present in the test wafer map, and
generating a new reference wafer map corresponding to the test wafer map if the test wafer map has an unknown defect pattern.

13. The apparatus of claim 12 wherein the semiconductor wafer comprises a plurality of semiconductor wafers; and wherein said processor groups test wafer maps having at least one common defect pattern.

14. The apparatus of claim 13 wherein said processor generates a report indicating a frequency of test wafer maps having the at least one common defect pattern.

15. The apparatus of claim 12 wherein said processor performs a statistical smoothing operation on the test wafer pattern to delete random defects.

16. The apparatus of claim 12 wherein the at least one reference wafer map comprises a plurality of reference wafer maps and the wafer comprises a plurality of wafers; and wherein said processor groups the plurality of reference wafer maps and the plurality of test wafer maps to provide a reference wafer lot.

17. The apparatus of claim 12 wherein said processor causes the new reference wafer map to be stored in said memory.
